(19) United States
(12) Patent Application Publication
(10) Pub. No.: US 2012/0274611 A1
(43) Pub. Date: Nov. 1, 2012

(54) THIN FILM TRANSISTORS (TFT) ACTIVE-MATRIX IMOD PIXEL LAYOUT

(75) Inventors: Jae Hyeong Seo, San Jose, CA (US); Marc Maurice Mignard, San Jose, CA (US); Ming-Hau Tung, San Jose, CA (US); Russel Allyn Martin, San Jose, CA (US)

(73) Assignee: QUALCOMM MEMS TECHNOLOGIES, INC., San Diego, CA (US)

(21) Appl. No.: 13/094,480

(22) Filed: Apr. 26, 2011

(51) Int. Cl. G09G 5/00; H01L 33/58

(52) U.S. Cl. 345/204; 438/29; 257/E33.071

(57) ABSTRACT

This disclosure provides systems, methods and apparatus relating to pixel designs for use in active matrix displays which employ poly-silicon (p-Si) thin-film transistors (TFTs) having dual gate structures to control the pixels. The poly-silicon island of the TFT is configured to take advantage of the black mask area attributable to other non-reflective display components, thus enhancing the fill factor of the display.

### TECHNICAL FIELD

This disclosure relates to electromechanical systems and more particularly to thin-film transistors structures and microelectromechanical system devices and systems that include such structures.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

In active-matrix IMOD display applications, the actuation of IMODs is often achieved using thin-film transistors (TFTs) as pixel switches. Some implementations employ poly-silicon (p-Si) TFTs because of the superior carrier mobility relative to amorphous-silicon TFTs (e.g., 200 cm²/Vs compared to 0.5 cm²/Vs). However, p-Si TFTs may be characterized by high leakage current. The leakage current of p-Si TFTs can be significantly reduced through the use of dual gate structures (e.g., up to one order of magnitude while on-current is reduced by only half). This is due to a voltage dividing effect that lowers the electric field between the source and drain of the device. However, conventional dual gate structures for TFTs typically result in an area penalty that undesirably reduces the fill factor of the display (i.e., the fraction of the display area occupied by IMOD reflective elements) and therefore its brightness.

The area penalty associated with a conventional dual gate poly-silicon TFT is due to the gate poly-silicon island of such a device being larger than the gate poly-silicon island of a conventional single gate TFT to accommodate the two fingers of the gate electrode of the dual gate TFT and the separation between them. The unsymmetrical dual gate structure causes other undesirable process related issues and, in some cases, can cause non-identical pixel mechanical response which is also undesirable.

### SUMMARY

The systems, methods and devices of the disclosure each have several innovative aspects, no single one of which is solely responsible for the desirable attributes disclosed herein.

One innovative aspect of the subject matter described in this disclosure can be implemented in an active-matrix interferometric modulator (IMOD) display that includes an array of pixels. Each pixel includes at least one of an IMOD and a pixel actuation switch. Each IMOD has a plurality of support posts occupying a black mask area of the display. Selection circuitry is configured to selectively activate the pixels in the array. The selection circuitry includes a plurality of gate buses disposed between the pixels in a first direction, and a plurality of data buses disposed between the pixels in a second direction. Each gate bus is electrically coupled to gate structures of the pixel actuation switches of a corresponding subset of the pixels arranged in a line in the first direction. Each data bus is electrically coupled to a terminal of the actuation switches of a corresponding subset of the pixels arranged in a line in the second direction. Each pixel actuation switch includes a poly-silicon thin-film transistor (TFT). The gate structure of each poly-silicon TFT is a poly-silicon dual gate structure that extends around an intersection point defined by the corresponding gate bus and the corresponding data bus to which the poly-silicon TFT is electrically coupled such that the poly-silicon dual gate structure coincides with at least a portion of the black mask area of the support post of four of the IMODs adjacent the intersection point.

Another innovative aspect of the subject matter described in this disclosure can be implemented in a display that includes an array of pixels. Each pixel includes at least one of a reflective means for controllably reflecting incident light and a switch means for actuating the reflective means. Each reflective means hays non-reflective structural components occupying a black mask area of the display. The display also includes selection means for selectively activating the pixels in the array. The selection means includes a plurality of gate buses disposed between the pixels in a first direction, and a plurality data buses disposed between the pixels in a second direction. Each gate bus is electrically coupled to a gate means for controlling the switch means of a corresponding subset of the pixels arranged in a line in the first direction. Each data bus is electrically coupled to a terminal of the switch means of a corresponding subset of the pixels arranged in a line in the second direction. The gate means of each switch means extends around an intersection point defined by the corresponding gate bus and the corresponding data bus to which the switch means is electrically coupled such that the gate means coincides with at least a portion of the black mask area of the non-reflective structural components of four of the reflective means adjacent the intersection point.

Another innovative aspect of the subject matter described in this disclosure can be implemented in an electronic device that includes a processor, a memory subsystem communicatively coupled to the processor, and an active-matrix reflective display communicatively coupled to and controlled by the processor. The display includes an array of pixels. Each pixel includes at least one of a reflective element and a pixel actuation switch. Each reflective element has a plurality of support posts occupying a black mask area of the display. The display also includes selection circuitry configured to selectively activate the pixels in the array. The selection circuitry includes a plurality of gate buses disposed between the pixels in a first direction, and a plurality data buses disposed between the pixels in a second direction. Each gate bus is electrically coupled to gate structures of the pixel actuation switches of a corresponding subset of the pixels arranged in a line in the first direction. Each data bus is electrically coupled to a terminal of the actuation switches of a corresponding subset of the pixels arranged in a line in the second direction. Each pixel actuation switch includes a thin-film transistor (TFT). The gate structure of each TFT is a dual gate structure that extends around an intersection point defined by the corresponding gate bus and the corresponding data bus to which the TFT is electrically coupled such that the dual gate structure coincides with at least a portion of the black mask area of the support post of four of the reflective elements adjacent the intersection point.

Another innovative aspect of the subject matter described in this disclosure can be implemented in a method for manufacturing an active-matrix reflective display having an array of pixels. Each pixel includes at least one of a reflective element and a pixel actuation switch. Each reflective element has a plurality of support posts occupying a black mask area of the display. A plurality of the pixel actuation switches is formed configured to selectively activate corresponding ones of the pixels in the array. A plurality of gate buses is formed disposed between the pixels in a first direction. Each gate bus is electrically coupled to gate structures of the pixel actuation switches of a corresponding subset of the pixels arranged in a line in the first direction. A plurality data buses is formed disposed between the pixels in a second direction. Each data bus is electrically coupled to a terminal of the actuation switches of a corresponding subset of the pixels arranged in a line in the second direction. Each pixel actuation switch includes a thin-film transistor (TFT). The gate structure of each TFT is a dual gate structure that extends around an intersection point defined by the corresponding gate bus and the corresponding data bus to which the TFT is electrically coupled such that the dual gate structure coincides with at least a portion of the black mask area of the support post of four of the reflective elements adjacent the intersection point. An optical stack is formed over the gate buses, data buses, and pixel actuation switches. A sacrificial layer is formed over the optical stack. The sacrificial layer is patterned to form support structure apertures. Support structure material is deposited into the apertures to form the support posts. A movable reflective layer is formed over the support posts. Cavities are formed under the movable reflective layer and between the support posts by removing the sacrificial material, thereby forming the reflective elements.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a simplified schematic illustration of a pixel of an active-matrix IMOD display.

FIG. 10 shows an example of a dual gate poly-silicon structure for use with an IMOD pixel.

FIG. 11A shows an example of a portion of an IMOD display including dual gate poly-silicon structures.

FIG. 11B shows an example of a conventional dual-gate TFT in the context of an IMOD display.

FIGS. 12A and 12B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

Various implementations described herein provide pixel designs for use in interferometric modulator (IMOD) displays which employ poly-silicon (p-Si) thin-film transistors (TFTs) having dual gate structures to control the IMODs. The poly-silicon TFT structure is configured to take advantage of the black mask area attributable to other display components, e.g., IMOD support posts, thus improving the fill factor of the display relative to previous TFTs having dual gate structures. The term “fill factor” refers to the percentage of the active area of a display relative to its total area. From a fill factor perspective, the areas of the display covered by or attributable to the black mask material may be considered parasitic, because they reduce the overall brightness of the reflected light. Therefore, reducing the display area attributable to black mask is a way to enhance the fill factor.

Despite references to IMOD display implementations, it should be noted that implementations are contemplated in which pixel designs described herein are used in other display types. For example, one class of implementations relates to electrowetting displays. Pixel designs as described herein may be advantageous in such displays, particularly when operated in a subtractive mode with stacked pixels (e.g., programmable filters of yellow, cyan and magenta).

Particular implementations of the subject matter described in this disclosure can be implemented to realize one or more of the following potential advantages. For example, the benefit of the low leakage current of dual gate p-Si TFTs may be enjoyed while mitigating the fill factor penalty associated with conventional dual gate TFT structures. Other potential advantages relate to the fact that incident light can increase the leakage current of p-Si TFTs. For example, by taking advantage of the black mask area attributable to non-reflective display components, this undesirable effect also may be mitigated. Still other potential advantages relate to the shape of some dual-gate structures implemented as described herein. The shape of such structures can lead to better pixel symmetry (not only in the x-y plane, but also in the z-axis), a potentially advantageous characteristic in arrays of MEMS devices.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

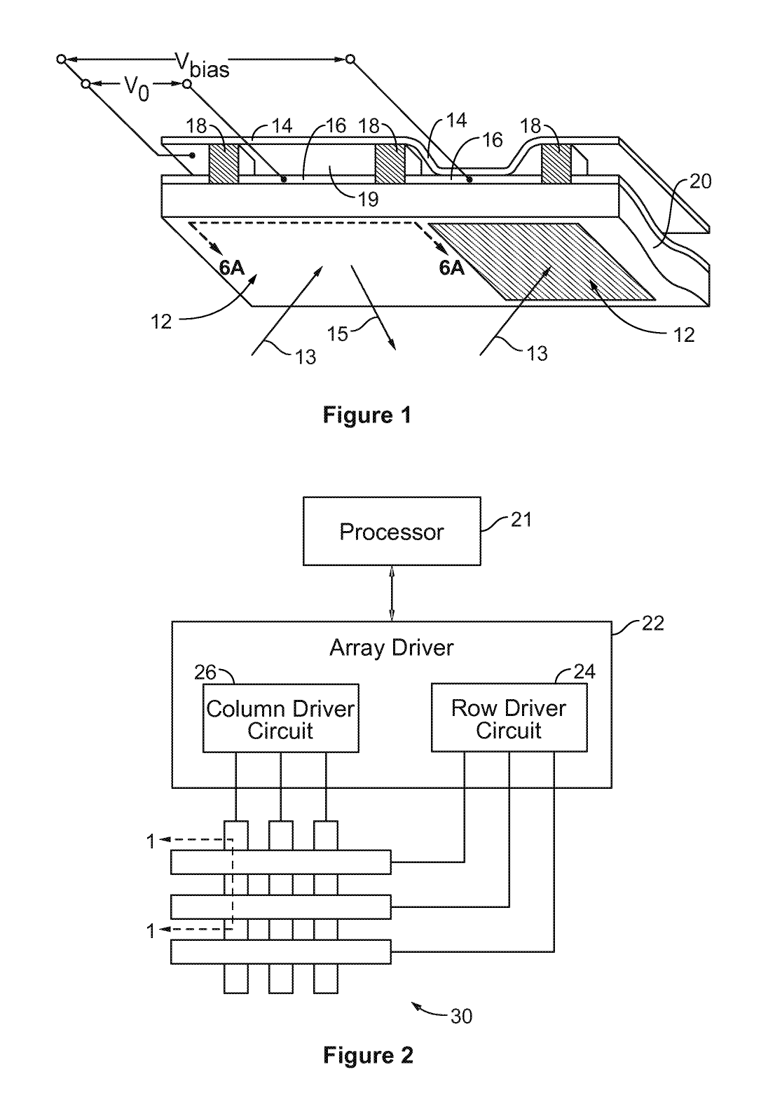

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

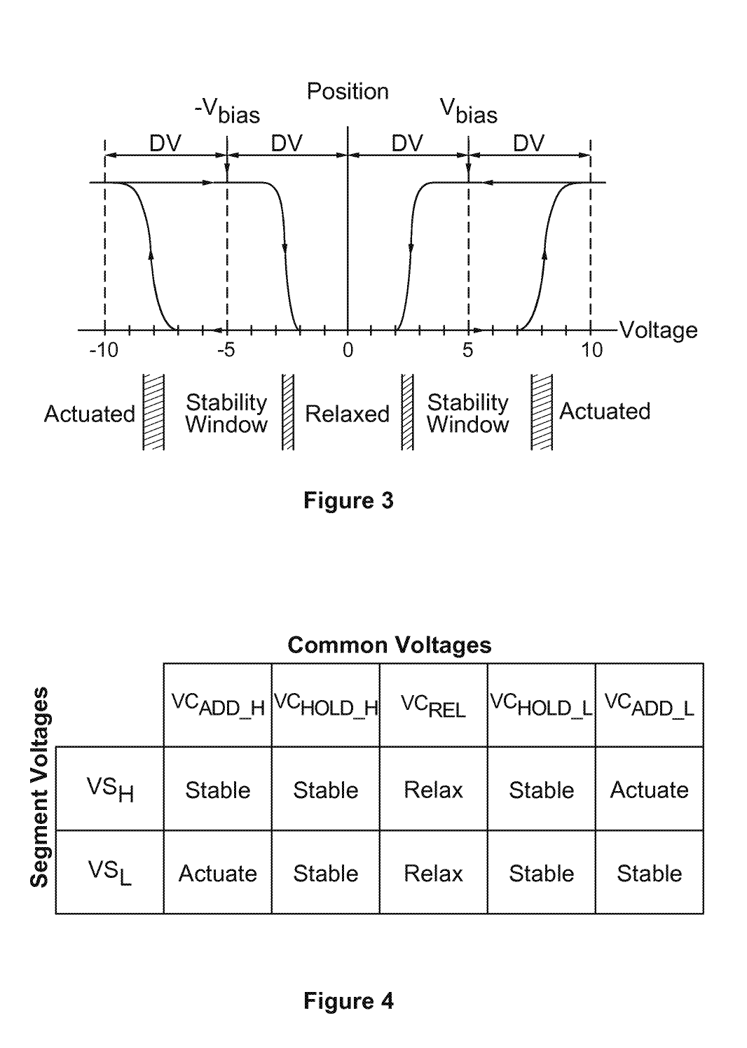

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

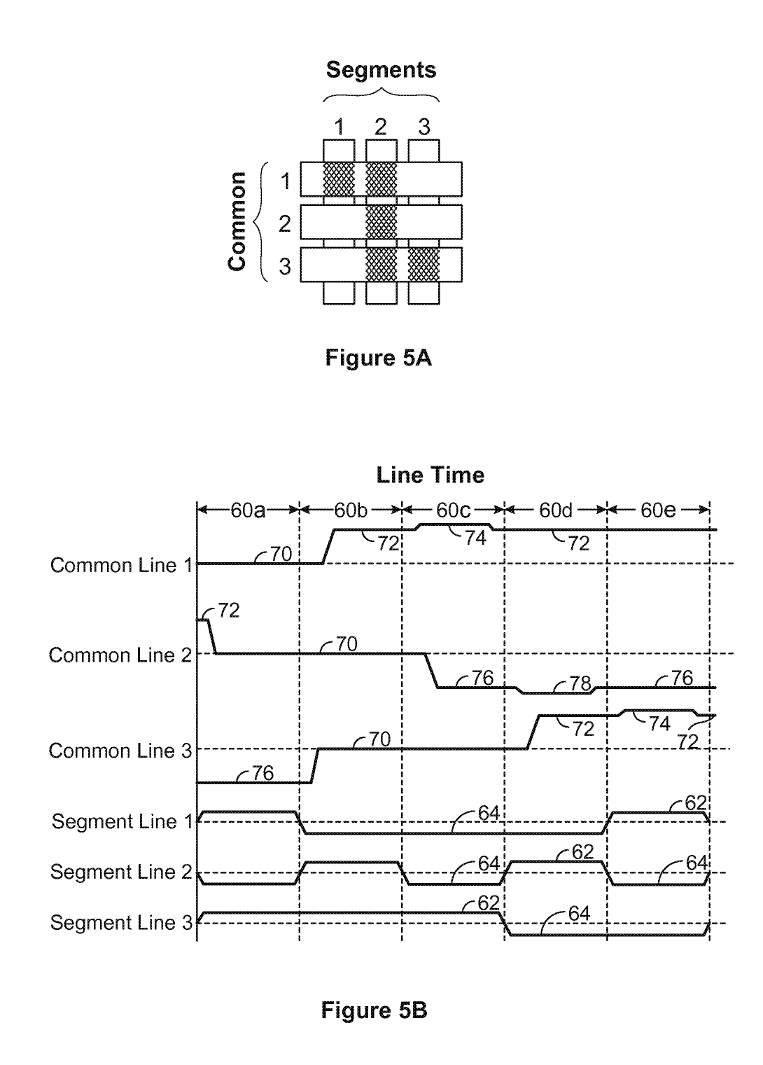

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

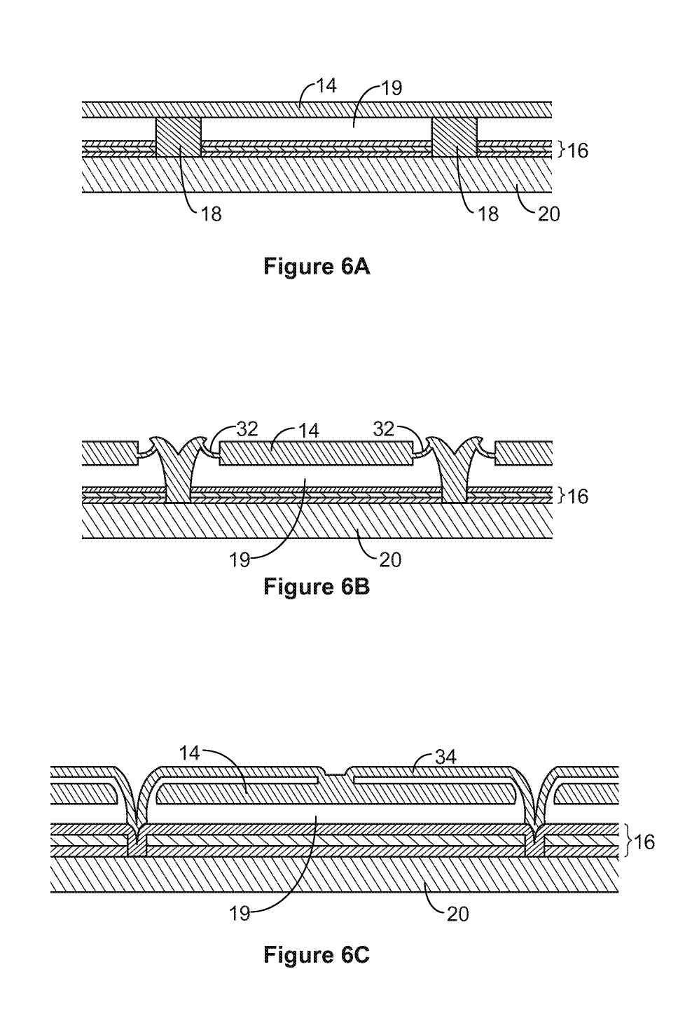

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

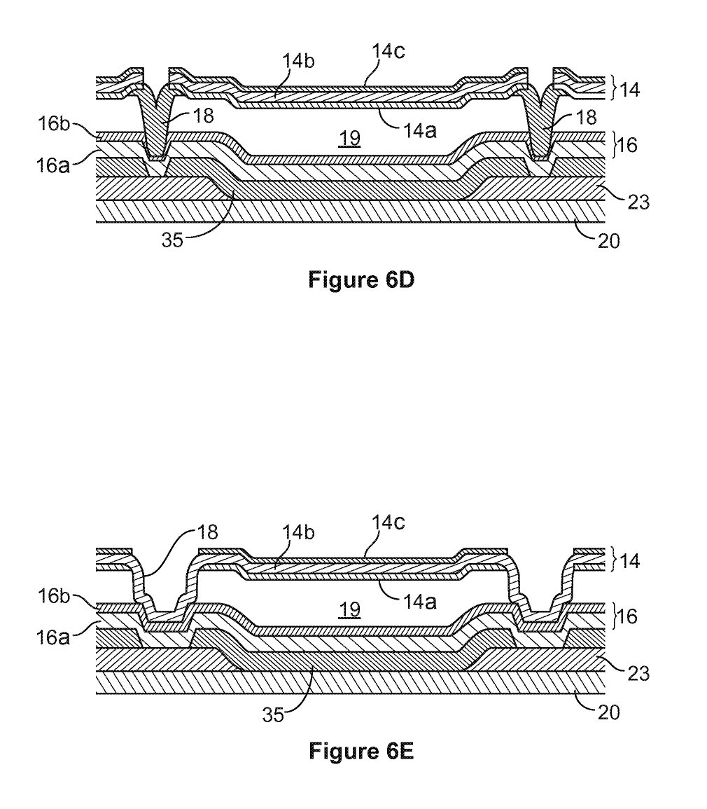

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

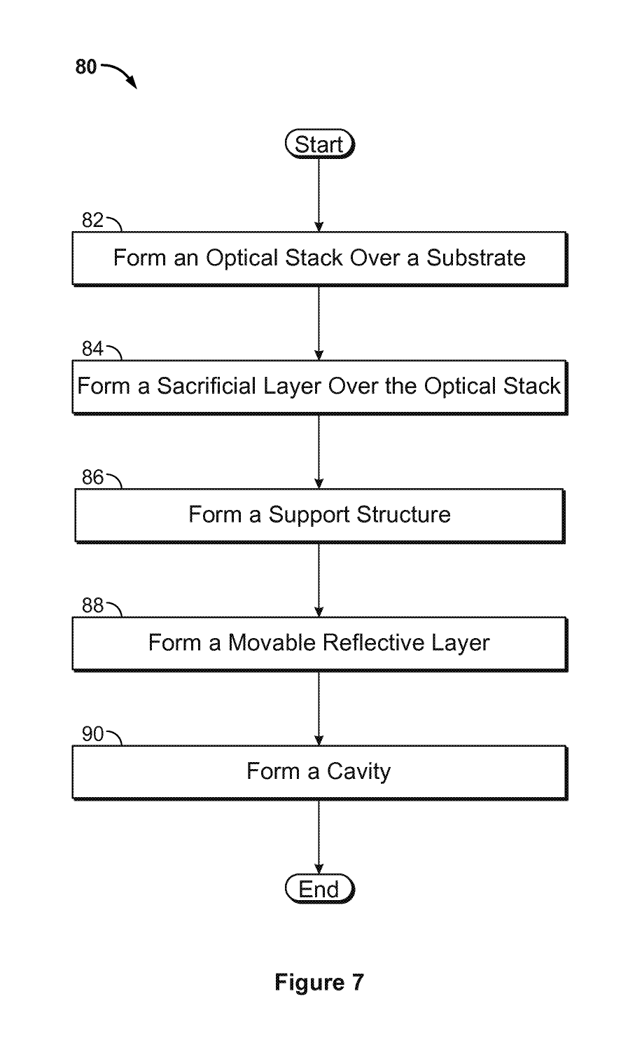

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

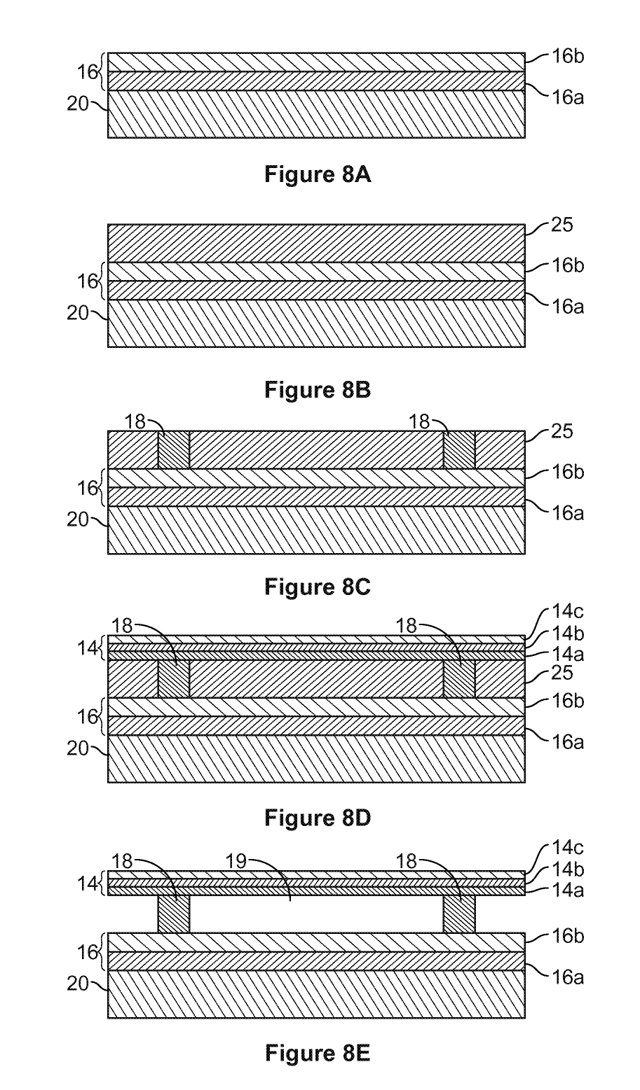

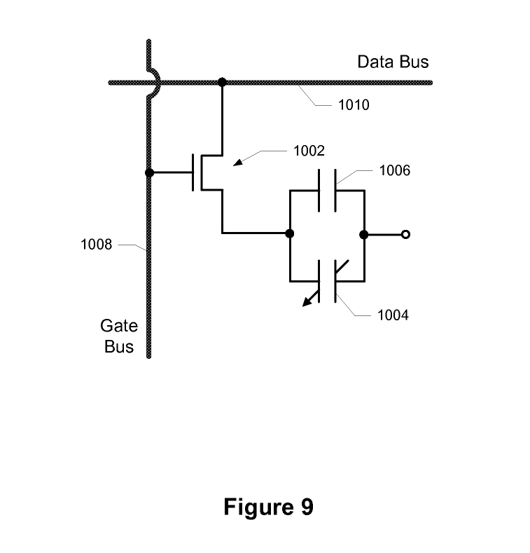

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

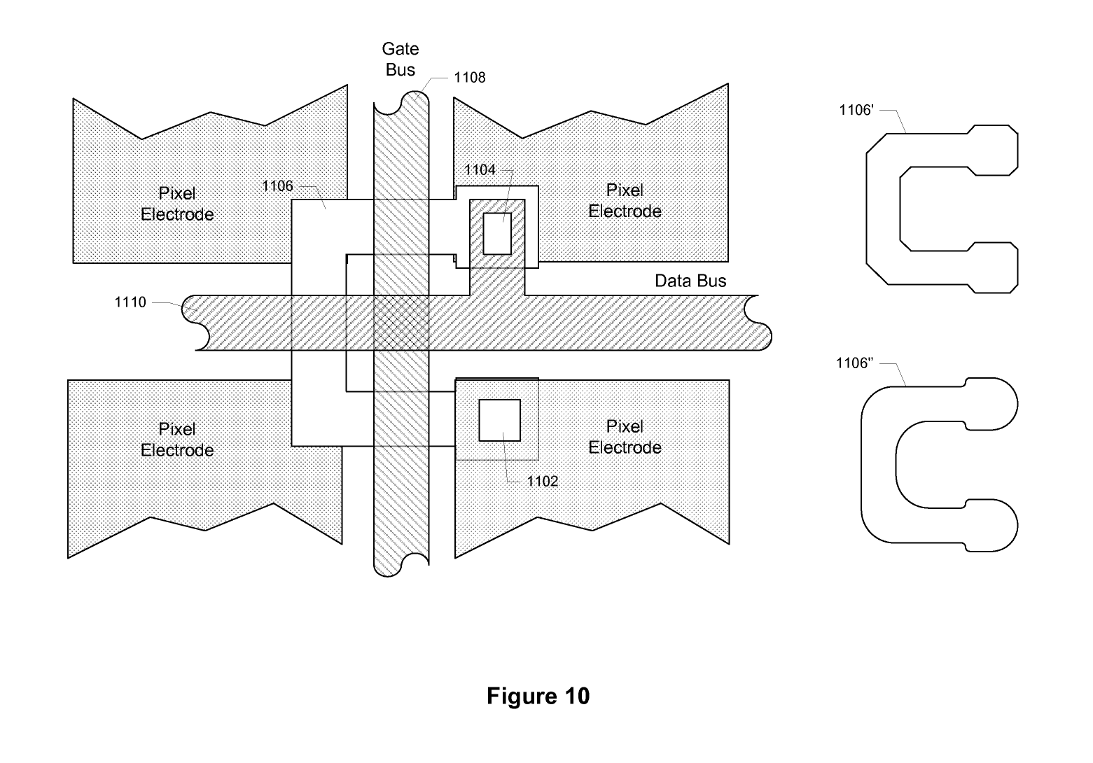

Active-matrix displays constructed from interferometric modulators (IMODs) as compared to passive-matrix IMOD displays can exhibit the following qualities, for example, low power consumption, high frame (video) rate, and better image quality (e.g., improved color uniformity and reduced cross-coupling). FIG. 9 shows an example of a simplified schematic illustration of a pixel of an active-matrix IMOD display. As shown, each pixel includes a pixel switch 1002, an IMOD 1004, and a storage capacitor 1006. According to some implementations, pixel switch 1002 may be a poly-silicon (poly-Si) thin-film transistor (TFT) having a dual gate structure which is coupled to gate bus 1008 (sometimes referred to as a scan bus). The source of the TFT is coupled to data bus 1010, and the drain is coupled to the pixel electrode of IMOD 1004 (although these connections may be reversed).

Inactive areas of an IMOD display are commonly referred to as “black mask” or “black matrix” areas of the display, and typically incorporate materials that absorb or attenuate light so that the optical response produced by the IMODs is not degraded by the reflection of ambient light from these areas. For example, it is not desirable to have light reflecting from IMOD posts or other support structures, as that light can interfere with the desired wavelengths of light reflected from IMOD pixels. Therefore, black mask material may be deposited under the post areas of the display, and/or such structures may be fabricated from non-reflective materials. Black mask materials also may be used to block light from the “bending region” of the IMOD mechanical layer near the posts, which is not flat when the mechanical layer is activated.

Another function of black mask material is to form part of the circuitry of the pixel array such as, for example, the gate and data buses by which control signals are transmitted to the pixels of the array. To accomplish this, at least one layer of the black mask may be formed of a conductive material. As discussed above, reducing the display area attributable to black mask is a way to enhance the fill factor.

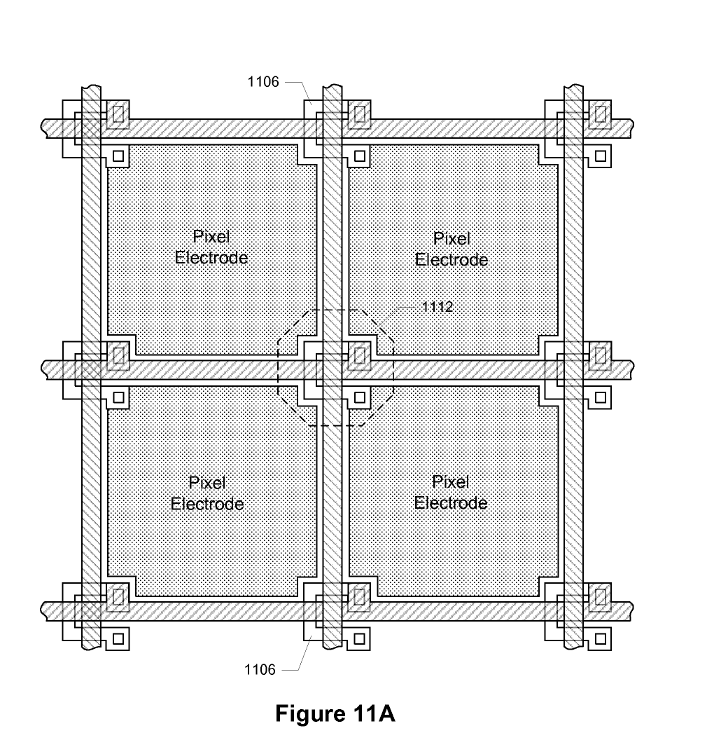

FIG. 10 shows an example of a dual gate poly-silicon structure for use with an IMOD pixel. Rather than extending in a direct line between source via 1102 and drain via 1104, active poly-silicon island 1106 is “U-shaped” (or “C-shaped), extending around the intersection of gate bus 1108 and data bus 1110.

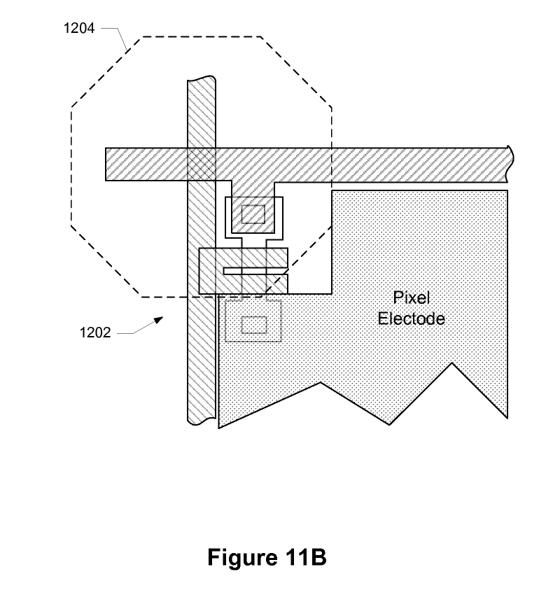

FIG. 11A shows an example of a portion of an IMOD display including dual gate poly-silicon TFT structures. As can readily be seen with reference to FIGS. 10 and 11A, the configuration of each poly-silicon island 1106 substantially coincides with non-reflective components (not shown), e.g., the support post(s), of the four IMODs adjacent each bus intersection. In the example implementation shown in FIG. 11A, four adjacent pixels share an octagonal support post 1112 (indicated by the dashed line). It should be noted that support post 1112 is merely an example and that other shapes (e.g., square, rectangular, circular, etc.) may be employed, as well as multiple posts around each intersection instead of one. FIGS. 1, 6A-6E, and 8E which show examples of various IMOD configurations also have non-reflective components, e.g., corner support posts, at similar locations. The poly-silicon island 1106 is configured such that a significant portion of the poly-silicon material occupies area that is black mask area attributable to such non-reflective components, e.g., support structures. This is to be contrasted with the typical conventional dual-gate TFT. FIG. 11B shows an example of a conventional dual-gate TFT in the context of an IMOD display. As shown, the dual-gate configuration of TFT 1202 results in a considerable portion of the TFT being outside of the same black mask area 1204.

And unlike the conventional dual gate structure, the depicted approach does not require the source and drain vias of the underlying TFT to be further apart than the conventional single gate structure. It should be understood, however, that implementations are contemplated in which the spacing between the source and drain vias is different or even greater than that of a single gate implementation.

In fact, as will be understood by those having ordinary skill in the art, a variety of configurations of poly-silicon island 1106 are contemplated that take advantage of the placement and shape of any of a variety of IMOD non-reflective components (e.g., support structures), as well as variations in the placement and orientation of source and drain vias, and/or the source and drain configurations of the underlying TFTs. For example, poly-silicon island 1106 of FIGS. 10 and 11A is shown having rectangular features with sharp corners. However, it will be understood that the features of poly-silicon island 1106 may be truncated (e.g., 1106′) or rounded off (e.g., 1106″) to varying degrees in some implementations. Other suitable variations are contemplated for particular applications. Moreover, TFTs having dual gate structures as described herein may be fabricated using any of a wide variety of conventional and proprietary techniques understood by and available to those of ordinary skill in the art.

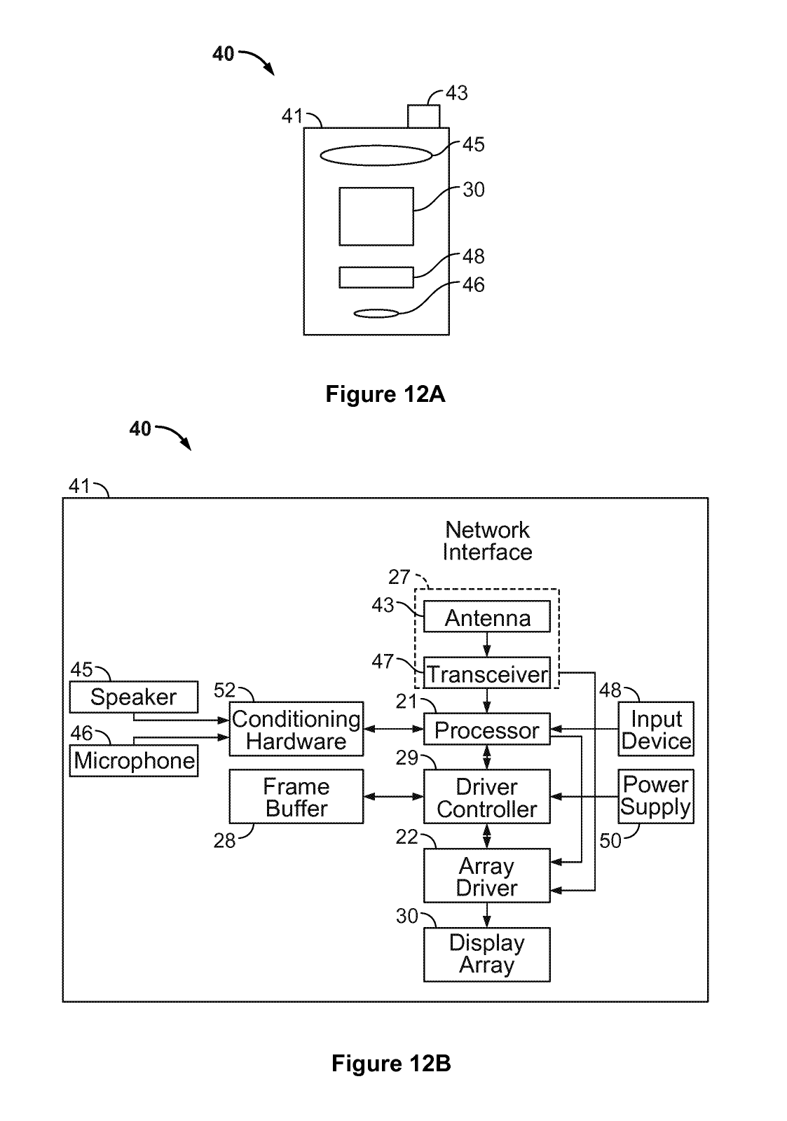

FIGS. 12A and 12B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 12B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11 a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a sub combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An active-matrix interferometric modulator (IMOD) display, comprising:
an array of pixels, each pixel including at least one of an IMOD and a pixel actuation switch, each IMOD having a plurality of support posts occupying a black mask area of the display; and
selection circuitry configured to selectively activate the pixels in the array, the selection circuitry including a plurality of gate buses disposed between the pixels in a first direction, and a plurality of data buses disposed between the pixels in a second direction, each gate bus being electrically coupled to gate structures of the pixel actuation switches of a corresponding subset of the pixels arranged in a line in the first direction, each data bus being electrically coupled to a terminal of the actuation switches of a corresponding subset of the pixels arranged in a line in the second direction;
wherein each pixel actuation switch includes a poly-silicon thin-film transistor (TFT), and wherein the gate structure of each poly-silicon TFT is a poly-silicon dual gate structure that extends around an intersection point defined by the corresponding gate bus and the corresponding data bus to which the poly-silicon TFT is electrically coupled such that the poly-silicon dual gate structure coincides with at least a portion of the black mask area of the support post of four of the IMODs adjacent the intersection point.

2. The active-matrix IMOD display of claim 1, wherein each poly-silicon dual gate structure includes a U-shaped structure extending around the corresponding intersection point.

3. The active-matrix IMOD display of claim 1, wherein each gate bus includes a substantially straight portion proximate each of the gate structures of the pixel actuation switches of the corresponding subset of the pixels, and wherein each of the gate structures coincides with the corresponding straight portion of the corresponding gate bus at multiple locations.

4. The active-matrix IMOD display of claim 1, wherein a source via and a drain via associated with each pixel actuation switch are aligned substantially parallel to the first direction.

5. The active-matrix IMOD display of claim 1, further comprising:
a processor that is configured to communicate with the array of pixels and the selection circuitry, the processor being configured to process image data; and
a memory device that is configured to communicate with the processor.

6. The active-matrix IMOD display of claim 5, further comprising a driver circuit configured to send at least one signal to the display.

7. The active-matrix IMOD display of claim 6, further comprising a controller configured to send at least a portion of the image data to the driver circuit.

8. The active-matrix IMOD display of claim 5, further comprising an image source module configured to send the image data to the processor.

9. The active-matrix IMOD display of claim 8, wherein the image source module includes at least one of a receiver, transceiver, and transmitter.

10. The active-matrix IMOD display of claim 5, further comprising an input device configured to receive input data and to communicate the input data to the processor.

11. A display, comprising:
an array of pixels, each pixel including at least one of a reflective means for controllably reflecting incident light and a switch means for actuating the reflective means, each reflective means having non-reflective structural components occupying a black mask area of the display; and
selection means for selectively activating the pixels in the array, the selection means including a plurality of gate buses disposed between the pixels in a first direction, and a plurality data buses disposed between the pixels in a second direction, each gate bus being electrically coupled to a gate means for controlling the switch means of a corresponding subset of the pixels arranged in a line in the first direction, each data bus being electrically coupled to a terminal of the switch means of a corresponding subset of the pixels arranged in a line in the second direction;
wherein the gate means of each switch means extends around an intersection point defined by the corresponding gate bus and the corresponding data bus to which the switch means is electrically coupled such that the gate means coincides with at least a portion of the black mask area of the non-reflective structural components of four of the reflective means adjacent the intersection point.

12. The display of claim 11, wherein each gate means includes a dual gate structure.

13. The display of claim 11, wherein each gate means includes a U-shaped structure extending around the corresponding intersection point.

14. The display of claim 11, wherein each gate bus includes a substantially straight portion proximate each of the gate means of the switch means of the corresponding subset of the pixels, and wherein each of the gate means coincides with the corresponding straight portion of the corresponding gate bus at multiple locations.

15. An electronic device, comprising:
a processor;
a memory subsystem communicatively coupled to the processor; and
an active-matrix reflective display communicatively coupled to and controlled by the processor, the display including,
an array of pixels, each pixel including at least one of a reflective element and a pixel actuation switch, each reflective element having a plurality of support posts occupying a black mask area of the display; and
selection circuitry configured to selectively activate the pixels in the array, the selection circuitry including a plurality of gate buses disposed between the pixels in a first direction, and a plurality data buses disposed between the pixels in a second direction, each gate bus being electrically coupled to gate structures of the pixel actuation switches of a corresponding subset of the pixels arranged in a line in the first direction, each data bus being electrically coupled to a terminal of the actuation switches of a corresponding subset of the pixels arranged in a line in the second direction;
wherein each pixel actuation switch includes a thin-film transistor (TFT), and wherein the gate structure of each TFT is a dual gate structure that extends around an intersection point defined by the corresponding gate bus and the corresponding data bus to which the TFT is electrically coupled such that the dual gate structure coincides with at least a portion of the black mask area of the support post of four of the reflective elements adjacent the intersection point.

16. The electronic device of claim 15, wherein each dual gate structure includes a U-shaped structure extending around the corresponding intersection point.

17. The electronic device of claim 15, wherein each gate bus includes a substantially straight portion proximate each of the gate structures of the pixel actuation switches of the corresponding subset of the pixels, and wherein each of the gate structures coincides with the corresponding straight portion of the corresponding gate bus at multiple locations.

18. The electronic device of claim 15, wherein the electronic device is selected from the group consisting of a mobile telephone, a multimedia Internet enabled cellular telephone, a mobile television receiver, a wireless device, a smartphone, a bluetooth device, a personal data assistants (PDA), a wireless electronic mail receiver, a hand-held computer, a portable computer, a netbook, a notebook, a smartbook, a tablet, a printer, a copier, a scanner, a facsimile device, a global positioning system (GPS) device, a camera, an MP3 player, a camcorder, a game console, a wrist watch, a clock, a calculator, a television monitor, a flat panel display, an electronic reading devices, a computer monitor, an automobile displays, a cockpit display, a camera view displays, an electronic photograph device, an electronic sign, a projector, an architectural structure, a kitchen appliance, a stereo system, a cassette recorder or player, a DVD player, a CD player, a video cassette recorder, a radio, a portable memory device, a parking meter, packaging, and an aesthetic structure.

19. A method for manufacturing an active-matrix reflective display having an array of pixels, each pixel including at least one of a reflective element and a pixel actuation switch, each reflective element having a plurality of support posts occupying a black mask area of the display, the method comprising:
forming a plurality of the pixel actuation switches configured to selectively activate corresponding ones of the pixels in the array;
forming a plurality of gate buses disposed between the pixels in a first direction, each gate bus being electrically coupled to gate structures of the pixel actuation switches of a corresponding subset of the pixels arranged in a line in the first direction;
forming a plurality data buses disposed between the pixels in a second direction, each data bus being electrically coupled to a terminal of the actuation switches of a corresponding subset of the pixels arranged in a line in the second direction;
wherein each pixel actuation switch includes a thin-film transistor (TFT), and wherein the gate structure of each TFT is a dual gate structure that extends around an intersection point defined by the corresponding gate bus and the corresponding data bus to which the TFT is electrically coupled such that the dual gate structure coincides with at least a portion of the black mask area of the support post of four of the reflective elements adjacent the intersection point, the method further comprising,
forming an optical stack over the gate buses, data buses, and pixel actuation switches;
forming a sacrificial layer over the optical stack;
patterning the sacrificial layer to form support structure apertures;
depositing support structure material into the apertures to form the support posts;
forming a movable reflective layer over the support posts; and
forming cavities under the movable reflective layer and between the support posts by removing the sacrificial material, thereby forming the reflective elements.

20. The method of claim 19, wherein each gate bus includes a substantially straight portion proximate each of the gate structures of the pixel actuation switches of the corresponding subset of the pixels, and wherein each of the gate structures coincides with the corresponding straight portion of the corresponding gate bus at multiple locations.
